(19) United States
(12) Patent Application Publication
(10) Pub. No.: US 2021/0365360 A1
(43) Pub. Date: Nov. 25, 2021

(54) MAPPING A VIRTUAL ADDRESS USING A CONTENT ADDRESSABLE MEMORY (CAM)

(71) Applicant: Micron Technology, Inc., Boise, ID (US)

(72) Inventors: Harold Robert G. Trout, Boise, ID (US); Troy D. Larsen, Meridian, ID (US); Timothy P. Finkbeiner, Boise, ID (US); Glen E. Hush, Boise, ID (US); Troy A. Manning, Meridian, ID (US)

(21) Appl. No.: 17/324,291

(22) Filed: May 19, 2021

Related U.S. Application Data
(60) Provisional application No. 63/027,487, filed on May 20, 2020.

(51) Int. Cl. G06F 12/02; G06F 12/06; G06F 12/1045; G11C 15/04

(52) U.S. Cl. CPC G06F 12/0238; G06F 12/0623; G11C 15/04; G06F 12/1054; G06F 12/1063

(57) ABSTRACT

Methods, apparatuses, and systems related to mapping a virtual address using a content addressable memory (CAM) are described. In a memory system including a memory and a content addressable memory (CAM), a select line of the CAM can be coupled to a corresponding select line of the memory, which allows the memory system to map a virtual address of a memory device directly to the corresponding select line of the memory. An example method can include receiving, from a host at a memory device comprising a memory array and a content addressable memory (CAM), a first virtual address to be searched among virtual addresses stored within the CAM, identifying, in response to receipt of the first virtual address, a select line of a plurality of select lines of the CAM associated with a second virtual address matching the first virtual address, and activating, in response to identifying the select line of the CAM, a corresponding select line of the memory coupled to the identified select line of the CAM.

### PRIORITY INFORMATION

This application claims priority of U.S. Provisional Application Ser. No. 63/027,487, filed on May 20, 2020, the contents of which are incorporated herein by reference.

### TECHNICAL FIELD

The present disclosure relates generally to semiconductor memory and methods, and more particularly, to apparatuses and methods related to mapping a virtual address using a content addressable memory (CAM).

### BACKGROUND

Memory devices are typically provided as internal, semiconductor, integrated circuits in computing systems. There are many different types of memory including volatile and non-volatile memory. Volatile memory can require power to maintain its data (e.g., host data, error data, etc.) and includes random access memory (RAM), dynamic random access memory (DRAM), static random access memory (SRAM), synchronous dynamic random access memory (SDRAM), and thyristor random access memory (TRAM), among others. Non-volatile memory can provide persistent data by retaining stored data when not powered and can include NAND flash memory, NOR flash memory, and resistance variable memory such as phase change random access memory (PCRAM), resistive random access memory (RRAM), and magnetoresistive random access memory (MRAM), such as spin torque transfer random access memory (STT RAM), among others.

Computing systems often include a number of processing resources (e.g., one or more processors), which may retrieve and execute instructions and store the results of the executed instructions to a suitable location. A processing resource can comprise a number of functional units such as arithmetic logic unit (ALU) circuitry, floating point unit (FPU) circuitry, and a combinatorial logic block, for example, which can be used to execute instructions by performing logical operations such as AND, OR, NOT, NAND, NOR, and XOR, and invert (e.g., inversion) logical operations on data (e.g., one or more operands). For example, functional unit circuitry may be used to perform arithmetic operations such as addition, subtraction, multiplication, and division on operands via a number of logical operations.

A number of components in a computing system may be involved in providing instructions to the functional unit circuitry for execution. The instructions may be executed, for instance, by a processing resource such as a controller and/or host processor. Data (e.g., the operands on which the instructions will be executed) may be stored in a memory array that is accessible by the functional unit circuitry. The instructions and data may be retrieved from the memory array and sequenced and/or buffered before the functional unit circuitry begins to execute instructions on the data. Furthermore, as different types of operations may be executed in one or multiple clock cycles through the functional unit circuitry, intermediate results of the instructions and data may also be sequenced and/or buffered.

### BRIEF DESCRIPTION OF THE DRAWINGS

FIG. 1 is a block diagram including a host coupled to a system configured to process and store data in accordance with a number of embodiments of the present disclosure.

FIG. 2 is a block diagram of an apparatus for mapping a virtual address using a CAM in accordance with a number of embodiments of the present disclosure.

FIG. 3 is a block diagram of mapping a virtual address using a CAM in accordance with a number of embodiments of the present disclosure.

FIG. 4 is a block diagram of an apparatus for mapping a virtual address using CAMs in accordance with a number of embodiments of the present disclosure.

FIG. 5 illustrates a memory cell of a memory in accordance with a number of embodiments of the present disclosure.

FIG. 6 illustrates a memory cell of a CAM in accordance with a number of embodiments of the present disclosure.

FIG. 7 is a timing diagram of a memory device for mapping a virtual address using a CAM in accordance with a number of embodiments of the present disclosure.

FIG. 8 is a flow diagram of a method for performing a lookup operation on data values stored in a CAM in accordance with a number of embodiments of the present disclosure.

FIG. 9 is a flow diagram of a method for mapping a virtual address using a CAM in accordance with a number of embodiments of the present disclosure.

### DETAILED DESCRIPTION

Methods, apparatuses, and systems related to mapping a virtual address using a content addressable memory (CAM) are described. In a memory system including a memory and a content addressable memory (CAM), a select line of the CAM can be coupled to a corresponding select line of the memory, which allows the memory system to map a virtual address of a memory device directly to the corresponding select line of the memory. An example method can include receiving, from a host, a first virtual address whose corresponding virtual address is to be searched among virtual addresses stored within the CAM, identifying, in response to receipt of the first virtual address, a select line of a plurality of select lines of the CAM associated with a second virtual address matching the first virtual address, and activating, in response to identifying the select line of the CAM, a corresponding select line of the memory coupled to the identified select line of the CAM.

A memory can comprise a semiconductor material configured to store an electrical charge. However, such a semiconductor material may have slow switching capabilities. As such, a different semiconductor material having faster switching capabilities, but does not store an electrical charge well, may be used for logic circuitry coupled to the memory. Although a semiconductor material used for memory may have slow switching capabilities, the semiconductor material used for memory can have advantages over semiconductor materials having faster switching capabilities. These advantages can include, but are not limited to, a high degree of parallelism, closeness to data, and power efficiency.

At least one embodiment of the present disclosure can integrate functions of a memory management unit (MMU), such as mapping a virtual address to a physical address, cache management (e.g., mapping a physical address to a cache address), and cache select line activation (e.g., cache address to cache select line), into a single operation performed using a CAM. The parallel structure of a CAM can enable the CAM to perform this single operation faster than performing each step individually. At least one embodiment can map a virtual address directly to a line of a memory (e.g., a cache) without intervention from application software whatsoever. At least one embodiment can manage cache misses, page faults, and/or interrupt context switching, thereby reducing software overhead when there is a single memory media (e.g., no software supported secondary memory media such as disks, etc.).

A CAM can be configured to perform a wired OR operation to determine whether the CAM stores a particular data value. Such an OR operation can be referred to as a lookup operation or a logical disjunction. In some previous memory architectures, an address may be translated into a datum. A CAM, on the other hand, reverses this process and translates a datum to an address. In at least one embodiment, a CAM can process an address as if the address were a datum and activate a row select line in lieu of an output address. An address received by a CAM can be compared to data stored in every row of the CAM simultaneously via the wired OR operation. In at least one embodiment, a CAM can serve as a decoder for a memory coupled to the CAM. In at least one embodiment, a CAM can treat a received address as a symbolic address and offset pair. At least one embodiment can include translation of a symbolic address, which can be critical to improved self-control of internal resources of a memory.

A CAM can be a control point from which a memory device can orchestrate row address strobe (RAS) and/or column address strobe (CAS) chains to optimize data access. A CAM can be a choke point at which to impose security because all data can pass through the CAM and the CAM can be configured to include additional security fields and/or store global addresses.

In at least one embodiment, portions of a CAM can be locked with specific data to improve performance of the CAM. For example, locking at least one entry in a CAM can reduce, or even eliminate, the probability of an operating system (OS) getting stuck into an infinite loop when responding to an interrupt. As another example, locking data in a CAM can compel weighting factors in a machine learning application to be retained in memory coupled to the CAM and allowing a remaining portion of the memory to operate as a cache. These arrangements can enable core low-level code or data to operate at an improved efficiency (e.g., out of static random access memory (SRAM)) while still providing virtual addressing.

In the following detailed description of the present disclosure, reference is made to the accompanying drawings that form a part hereof, and in which is shown by way of illustration how one or more embodiments of the disclosure may be practiced. These embodiments are described in sufficient detail to enable those of ordinary skill in the art to practice the embodiments of this disclosure, and it is to be understood that other embodiments may be utilized and that process, electrical, and/or structural changes may be made without departing from the scope of the present disclosure. As used herein, designators such as “n, “N,” etc., particularly with respect to reference numerals in the drawings, indicate that a number of the particular feature so designated can be included. As used herein, “a number of” a particular thing refers to one or more of such things (e.g., a number of memory arrays can refer to one or more memory arrays). A “plurality of” is intended to refer to more than one of such things.

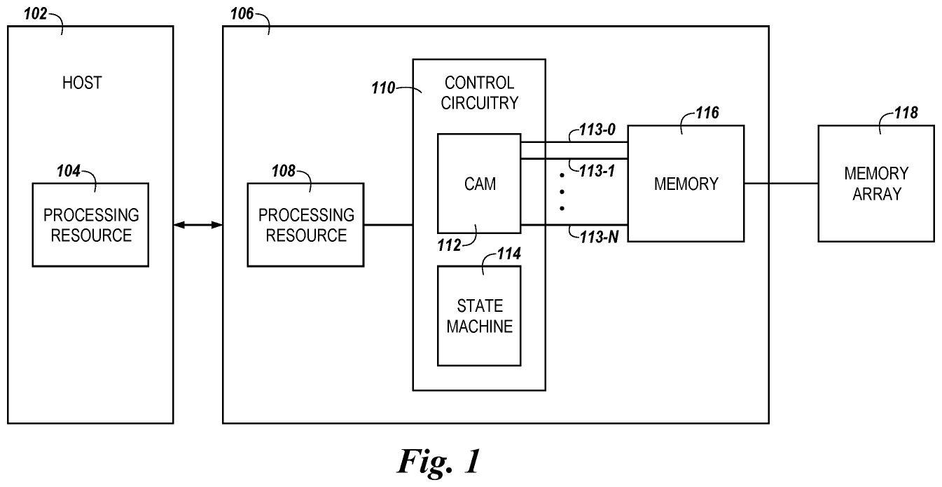

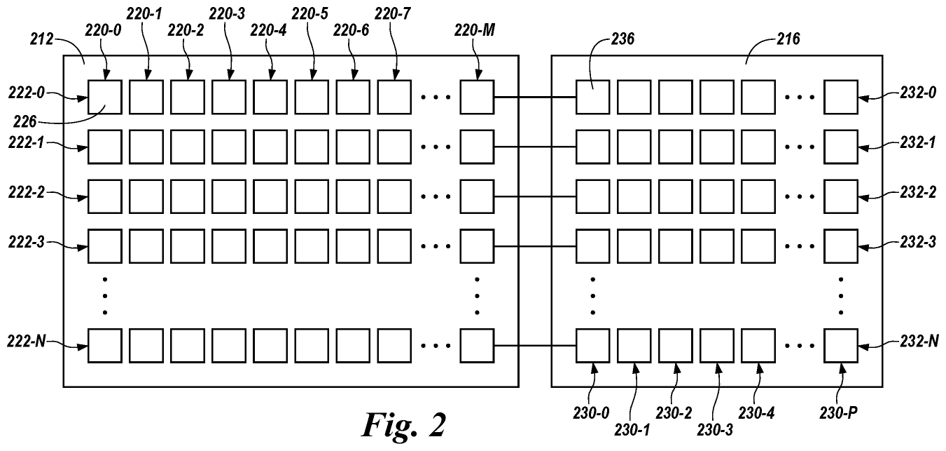

The figures herein follow a numbering convention in which the first digit or digits correspond to the drawing figure number and the remaining digits identify an element or component in the drawing. Similar elements or components between different figures may be identified by the use of similar digits. For example, 102 may reference element “02” in FIG. 1, and a similar element may be referenced as 202 in FIG. 2. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention, and should not be taken in a limiting sense.

FIG. 1 is a block diagram including a host coupled to a system configured to process and store data in accordance with a number of embodiments of the present disclosure. System 100 can include an apparatus 106 coupled to the host and configured to process data using processing resource 108 and memory 116. Processing resource 108 can be a RISC-V processor, for example. System 100 can also include apparatus 106 coupled to memory array 118. Memory array 118 can provide main memory for system 100 and can also provide storage as a backing store for system 100.

Memory array 118 can include control circuitry 111 configured to maintain data stored in tables in memory array 118 in sorted order. The sorted order can be based on keys associated with the data stored in memory array 118. The data stored in tables in sorted order can allow access to data based on upon the keys and/or the sorted order of the data, which can increase access times to data the memory array.

Apparatus 106 can include control circuitry 110 configured to directly map an address received from processing resource 108 and/or host 102 to a row in memory 116. Control circuitry 110 can include CAM 112 that is configured to receive an address and perform a look up operation for the address in CAM 112 and open a row in memory 116 in response to locating the address in CAM 112 in the look up operation. The look up operation can locate the address in a row of the CAM 112 that is directly coupled to the row in memory 116 and CAM 112 can be configured to open a row in memory 116 that is coupled to the row in the CAM 112 where the address is located.

The control circuitry 110 can be coupled to the memory 116. The memory 116 can be coupled to the memory array 118. The control circuitry 110 can include a CAM 112. In at least one embodiment, the CAM 112 can be on chip with the processing resource 108 and the memory 116. In at least one embodiment, the control circuitry 110 can include a state machine 114 (e.g., a finite state machine (FSM)) in communication with the CAM 112. The state machine 114 can generate operation codes (hereinafter referred to as “opcodes”) and provide opcodes to the CAM 112. The opcodes can control operations performed by the CAM 112 described herein, such as a lookup operation. The CAM 112 can be coupled to the memory 116. A single select line of the CAM 112 can be coupled to a single select line of the memory 116 as represented by lines 113-0, 113-1, . . . , 113-N. In at least one embodiment, the memory 116 can be SRAM. However, embodiments of the present disclosure are not so limited.

As described herein, in at least one embodiment, the CAM 112 can be configured to, during a time period associated with executing an access command (e.g., concurrently), map a virtual address of the memory array 118, wherein the virtual address can be received as address information associated with an access command, to a corresponding physical address of the memory array 118, map the corresponding physical address of the memory array 118 to a corresponding physical address of the memory 116, and map the corresponding physical address of the memory 116 to a row of the memory 116. The CAM 112 can serve as a decoder for the memory 116.

The memory device 106 can be configured to intercept the virtual address from the host 102 and/or the processing resource 104. The CAM 112 can be configured to determine whether a first portion of rows of memory cells of the CAM 112 stores the intercepted virtual address and determine whether the second portion of the rows of memory cells of the CAM stores the physical address of the memory.

In at least one embodiment, the control circuitry 110 can be configured to perform fully associative caching. As used herein, “fully associative caching” refers to capability of the memory 116 to store data values at any address of the memory 116. In some previous approaches, n-way caches (e.g., 2-way, 4-way, or 8-way caches) may confine addresses to one or more specific cache groups, which may cause a greater quantity of address collisions than a fully associative caching according to the present disclosure. At least one embodiment can enable cache optimizing strategies that are not possible with previous approaches. For example, the control circuitry 110 can be configured to lock down data values of the CAM 112 without a significant reduction in operating efficiency of the control circuitry 110. The control circuitry 110 can operate at almost the same efficiency with a few data values stored in the CAM 112 locked as when no data values stored in the CAM 112 are locked. A benefit of locking data values of the CAM 112 can be ensuring that frequently referenced code and/or data values to remain stored in the CAM 112.

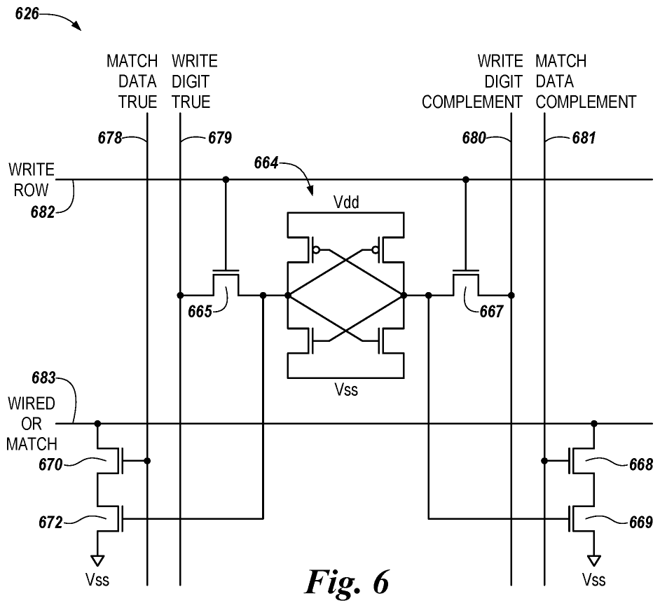

FIG. 2 is a block diagram of an apparatus for mapping a virtual address using the CAM 212 in accordance with a number of embodiments of the present disclosure. The CAM 212 and the memory 216 can be analogous to the CAM 112 and the memory 116, respectively, described in association with FIG. 1. The CAM 212 can include a plurality of memory cells 226 arranged in a plurality of columns 220-0, 220-1, 220-2, 220-3, 220-4, 220-5, 220-6, 220-7, . . . , 220-M (collectively referred to as columns 220) and a plurality of rows 222-0, 222-1, 222-2, 222-3, . . . , 222-N (collectively referred to as rows 222). The memory cells 226 are represented as squares for illustrative purposes only and is not intended to limit the shape and/or structure of the CAM cells 226. An exemplary CAM cell 226 of the CAM 212 is described in association with FIG. 6. The CAM cells 226 can be configured to perform a wired OR operation. The CAM 212 can be configured to perform a wired OR operation to determine whether an entry stored in the CAM 212 matches an input data value.

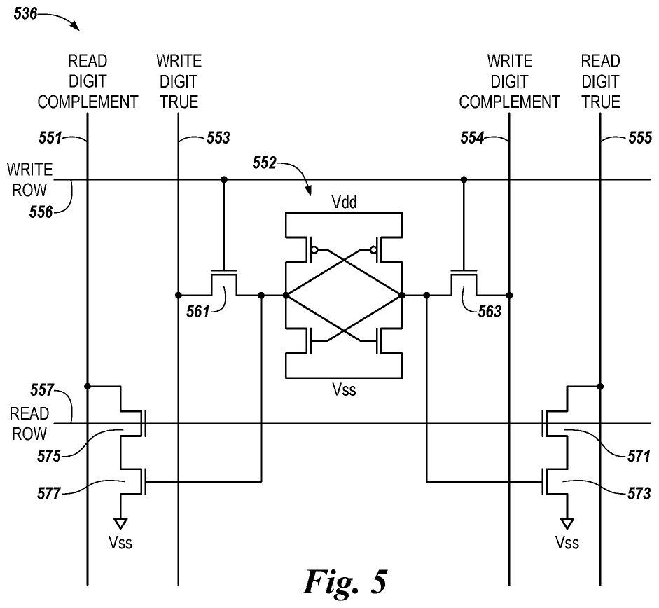

The memory 216 can include a plurality of memory cells 236 arranged in a plurality of columns 230-0, 230-1, 230-2, 230-3, 230-4, . . . , 230-P (collectively referred to as columns 230) and a plurality of rows 232-0, 232-1, 232-2, 232-3, . . . , 232-N (collectively referred to as rows 232). The CAM cells 226 are represented as squares for illustrative purposes only and is not intended to limit the shape and/or structure of the memory cells 236. An exemplary memory cell 236 of the memory 216 is described in association with FIG. 5. As illustrated in FIG. 2, a single row of CAM cells 226 of the CAM 212 (e.g., row 222-0) can be coupled to a single row of memory cells 236 of the memory 216 (e.g., row 232-0).

Although FIG. 2 illustrates the CAM 212 and the memory 216 having the same quantity (N+1) of rows 222 and 232, respectively, embodiments of the present disclosure are not so limited. For example, the CAM 212 can include N+1 rows 222 and the memory 216 can include N+2 rows 232. Although FIG. 2 illustrates the CAM 212 and the memory 216 having different quantities of columns (M+1 and P+1, respectively), embodiments of the present disclosure are not so limited. The quantity (M+1) of columns 220 can be less than, equal to, or greater than the quantity (P+1) of columns 230. As described herein, the quantity (M+1) of columns 220 of the CAM 212 can be based, at least partially, on the lengths of virtual addresses and/or physical addresses used by a memory array (not shown) to which the apparatus is coupled. The quantity (N+1) of rows 222 of the CAM 212 can be based, at least partially, on the quantity (N+1) of rows 232 of the memory 216.

The CAM 212 can include a first portion (e.g., a first subset of the CAM cells 226) of each row 222 configured to store a virtual address of a main memory (e.g., the memory array 118). For example, columns 220-0, 220-1, and 220-2 can be configured to store virtual addresses of a main memory. The CAM 212 can include a second portion (e.g., a second subset of the CAM cells 226) of each row 222 configured to store a physical address of the memory 216. For example, columns 220-3, 220-4, and 220-5 can be configured to store physical addresses of the memory 216. Embodiments are not limited to three CAM cells 226 storing a virtual address or a physical address.

The CAM 212 can be configured to store virtual addresses of the memory array in a first number of the columns 220 of the CAM cells 226. The CAM 212 can be configured to store physical addresses of the memory 216 in a second number of the columns 220 of the CAM cells 226. The CAM 212 can be configured to search the first number of the columns 220 for the virtual address. The CAM 212 can be configured to search the second number of the columns 220 for the physical address. The CAM 212 can be configured to disable the first number of columns in response to memory cells of the first number of the columns 220 not storing the virtual address. The CAM 212 can be configured to disable the second number of columns in response to CAM cells 226 of the second number of the columns 220 not storing the physical address.

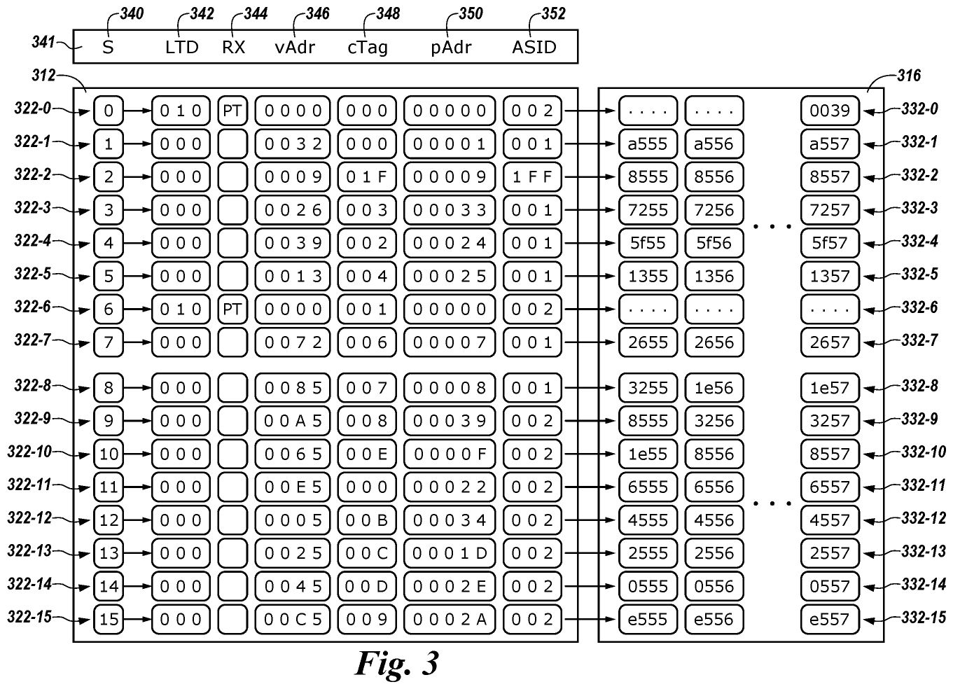

FIG. 3 is a block diagram of mapping a virtual address using the CAM 312 in accordance with a number of embodiments of the present disclosure. The data values, addresses, and structure of the CAM 312 and the memory 316 illustrated by FIG. 3 are exemplary and non-limiting. The CAM 312 can include rows 322-0, 322-1, 322-2, 322-3, 322-4, 322-5, 322-6, 322-7, 322-8, 322-9, 322-10, 322-11, 322-12, 322-13, 322-14, and 322-15. The memory 316 can include rows 332-0, 332-1, 332-2, 332-3, 332-4, 332-5, 332-6, 332-7, 332-8, 332-9, 332-10, 332-11, 332-12, 332-13, 332-14, and 332-15. As illustrated by FIG. 3, the row 322-0 of the CAM 312 can be coupled to row 332-0 of the memory 316, row 322-1 of the CAM 312 can be coupled to row 332-1 of the memory 316, row 322-2 of the CAM 312 can be coupled to row 332-2 of the memory 316, and so on.

A first portion 340 of the rows 322 of the CAM 312 can include one or more memory cells (e.g., the CAM cells 226 described in association with FIG. 2) configured to store a data value indicative of a row index (S) of the CAM 312. For example, the row 322-0 can store a data value indicative of row index 0, the row 322-1 can store a data value indicative of row index 1, the row 322-2 can store a data value indicative of row index 2, and so on. An opcode, generated by a state machine (not shown), can include a bit that enables or disables a lookup operation to be performed by the CAM 312 on data values stored in the first portion 340. For example, if a specific row of the CAM 312 or the memory 316 is to be singled out, then the first portion 340 of the CAM 312 can be enabled and all other portions of the CAM 312 can be disabled to unambiguously select the specific row. For example, if a row of the CAM 312 or the memory 316 is selected by a different operation (e.g., a different lookup operation), then the different operation can report out which row of the CAM 312 stores the received row index. This can reduce, or even eliminate, a need for prioritization logic to identify a selected row of the CAM 312 and/or a priority encode to perform a reverse-address lookup with the CAM 312. The first portion 340 can be used, dynamically or in post-manufacturing testing, for example, to avoid portions of the CAM 312 and/or the memory 316 that failed testing. This can enable the CAM 312 and the memory 316 to be over provisioned and the first portion 340 used to block out one or more rows of the CAM 312 and/or the memory 316 that are determined defective during testing.

A second portion 342 of the rows 322 of the CAM 312 can include one or more memory cells configured to store data values indictive of management data associated with a corresponding row of the memory 316. The management data can indicate whether data in a corresponding row of the memory 316 is locked (L), a page table entry (T), and/or dirty (D). For example, a first bit of the management data of one of the rows 322 of the CAM 312 can be set to 1 if data values stored in the corresponding row of the memory 316 is locked. An advantage of locking entries of the memory 316 is that frequently referenced code or data can be locked down (by a user, for example) to ensure that code or data is present when interrupt routines are declared, for example. Locking entries can be beneficial for referencing weighting tables of machine learning. A second bit of the management data one of the rows 322 of the CAM 312 can be set to 1 if data values stored in the corresponding row of the memory 316 is a page table entry. A third bit of the management data one of the rows 322 of the CAM 312 can be set to 1 if data values stored in the corresponding row of the memory 316 is dirty. If data values of the corresponding row of the memory 316 is dirty, then the data can be flushed (to a main memory, for example).

A third portion 344 of the rows 322 of the CAM 312 can include one or more memory cells configured to store data values indictive of management data associated with a corresponding row of the memory 316. The management data can indicate whether data in a corresponding row of the memory 316 is read-only or execute-only. For example, a first bit of the management data of the third portion 344 of one of the rows 322 of the CAM 312 can be set to 1 if data values stored in the corresponding row of the memory 316 is read-only. A second bit of the management data of the third portion 344 of one of the rows 322 of the CAM 312 can be set to 1 if data values stored in the corresponding row of the memory 316 is execute-only.

A fourth portion 346 of the rows 322 of the CAM 312 can include one or more memory cells configured to store virtual addresses (vAdr) of a memory array (e.g., the memory array 118 described in association with FIG. 1). An opcode, generated by a state machine (not shown), can include a bit that enables or disables a lookup operation to be performed by the CAM 312 on data values stored in the fourth portion 346 (a lookup operation on virtual addresses of the memory array stored in the CAM 312).

A fifth portion 348 of the rows 322 of the CAM 312 can include one or more memory cells configured to store data values indicative of physical addresses of the memory 316. A physical address of the memory 316 can be referred to as a cache tag (cTag). An opcode, generated by a state machine (not shown), can include a bit that enables or disables a lookup operation to be performed by the CAM 312 on data values stored in the fifth portion 348 (a lookup operation on physical addresses of the memory stored in the CAM 312).

A sixth portion 350 of the rows 322 of the CAM 312 can include one or more memory cells configured to store data values indicative of physical addresses (pAdr) of a memory array (e.g., the memory array 118). An opcode, generated by a state machine (not shown), can include a bit that enables or disables a lookup operation to be performed by the CAM 312 on data values stored in the sixth portion 350 (a lookup operation on physical addresses of the memory array stored in the CAM 312).

A seventh portion 352 of the rows 322 of the CAM 312 can include one or more memory cells configured to store data values indicative of address space identifiers (ASID). A subset of memory cells of each of the rows 332 can be configured to store an ASID. An ASID stored in one of the rows 322 of the CAM 312 can identify a process, thread, application, or task to which a virtual address of the memory array (vAdr), a physical address of the memory array (pAdr), and/or a physical address of the memory 316 (cTag) stored in that row of the CAM 312 correspond. For example, two different threads can utilize the same virtual address, but each thread can have a different ASID. This can be beneficial to maintain differentiation between multiple tasks, even though the CAM 312 may not be flushed on a task switch. For example, if a thread is deactivated and subsequently reactivated, then the thread can have valid entries in the CAM 312 from previous activation of the thread. This can enable threads to flit in and out of the CAM 312 while reducing loss efficiency in the memory 316. An opcode, generated by a state machine (not shown), can include a bit that enables or disables a lookup operation to be performed by the CAM 312 on data values stored in the seventh portion 352 (a lookup operation on ASIDs stored in the CAM 312).

The CAM 312 can receive signals and/or data values indicative of a virtual address of a memory array and a physical address of the memory 316. The signals can be received through a manifold 341 coupled to the CAM 312. The manifold 341 can be configured to expand a received opcode into a control register that determines which portions (e.g., columns) of the CAM 312 are enabled for a lookup operation according to the received opcode. The CAM 312 can be configured to control columns of the CAM 312 that are enabled during a lookup operation by manipulating raw and inverted values of each input field, such as address bits, for example. The CAM 312 can be configured to force complementary values of a column of the CAM 312 to both ones or both zeros to disable the column. Those columns not disabled participate in a lookup operation. No additional logic is needed in the CAM 312, which does not degrade space efficiency of the CAM 312.

The CAM 312 can be configured to perform a wired OR operation on the signals indicative of the virtual address of the memory array and the physical address of the memory 316, and virtual addresses of the memory array and physical addresses of the memory 316 stored in the CAM 312. The wired OR operation can compare the received virtual address of the memory array and the received physical address of the memory 316 to all virtual addresses of the memory array and physical addresses of the memory 316 stored in the CAM 312 simultaneously. The CAM 312 can be configured to, in response to determining that the received virtual address of the memory array and the received physical address of the memory 316 are stored in a row of the CAM 312, activate a corresponding received line (e.g., row) of the memory 316 coupled to that row of the CAM 312. The row of the CAM 312 that stores the received virtual address of the memory array and the physical address of the memory 316 stores a physical address of the memory array corresponding to the received virtual address.

The CAM 312 can be configured to map a virtual address of the memory array directly to a line of the memory 316. The CAM 312 can be configured to map a virtual address of the memory array to a physical address of the memory array, map the physical address of the memory array to a physical address of the memory 316, and map the physical address of the memory 316 to a line of the memory 316 in a single operation. This single operation can map a virtual address of the memory array to a line of the memory 316 faster than previous approaches that perform each mapping individually. At least one embodiment can be three to four times faster than previous approaches that perform each mapping individually.

The following describes an exemplary direct mapping of a virtual address of the memory array to a line of the memory 316 in accordance with the present disclosure. The CAM 312 can receive signals indicative of a hexadecimal virtual address 0065 of the memory array and hexadecimal physical address 00E of the memory 316. The CAM 312 can be configured to perform a wired OR operation on the virtual address 0065 and the physical address 00E, and the entries stored in the fourth portion 346 and fifth portion 348 of the CAM 312. The row 322-10 of the CAM 312 stores the virtual address 0065 and the physical address 00E. As result of the wired OR operation, the CAM 312 can be configured to activate the row 332-10 of the memory 316 coupled to the row 322-10 of the CAM 312. The memory 316 can be configured to output word 1e55 that is stored at the physical address 00E of the memory 316.

In at least one embodiment, the CAM 312 can receive a signal and/or data value indicative of an ASID (via the manifold 341, for example) with the received signals and/or data values indicative of the virtual address of the memory array and the physical address of the memory 316. In at least one embodiment, the CAM 312 can be configured to store ASIDs in a plurality of columns of memory cells of the CAM 312. The CAM 312 can be configured to search the plurality of columns for an ASID corresponding to the virtual address. The CAM 312 can be configured to disable the plurality of columns in response to memory cells of the plurality of columns not storing the ASID corresponding to the virtual address.

The CAM 312 can be configured to determine whether at least one entry of the CAM 312 includes a received virtual address of the memory array, the received physical address of the memory 316, and a received ASID. The CAM 312 can be configured to identify a select line of the CAM 312 associated with the received virtual address of the memory array, the received physical address of the memory 316, and the received ASID. The CAM 312 can be configured to activate the select line of the CAM coupled to the select line of the memory. The CAM 312 can be configured to receive an address (via the manifold 341, for example) including a first number of bits indicative of the received virtual address of the memory array, a second number of bits indicative of the received physical address of the memory 316, and a third number of bits indictive of the received ASID. The CAM 312 can be configured to receive the address from a processing resource (e.g., a RISC-V processor) that is on chip with the CAM 312.

The CAM 312 can be configured to perform a wired OR operation on the received signals and/or data values indicative of the virtual address of the memory array, the physical address of the memory 316, and the ASID, and virtual addresses of the memory array, physical addresses of the memory 316 and ASIDs stored in the CAM 312. The wired OR operation can compare the received virtual address of the memory array, the received physical address of the memory 316, and the received ASID to all virtual addresses of the memory array, physical addresses of the memory 316, and ASIDs stored in the CAM 312 simultaneously.

The CAM 312 can be configured to, in response to determining that the received virtual address of the memory array, the received physical address of the memory 316, and the received ASID are stored in a row of the CAM 312, activate a corresponding line (e.g., row) of the memory 316 coupled to that row of the CAM 312. The row of the CAM 312 that stores the received virtual address of the memory array, the received physical address of the memory 316, and the received ASID stores a physical address of the memory array corresponding to the received virtual address.

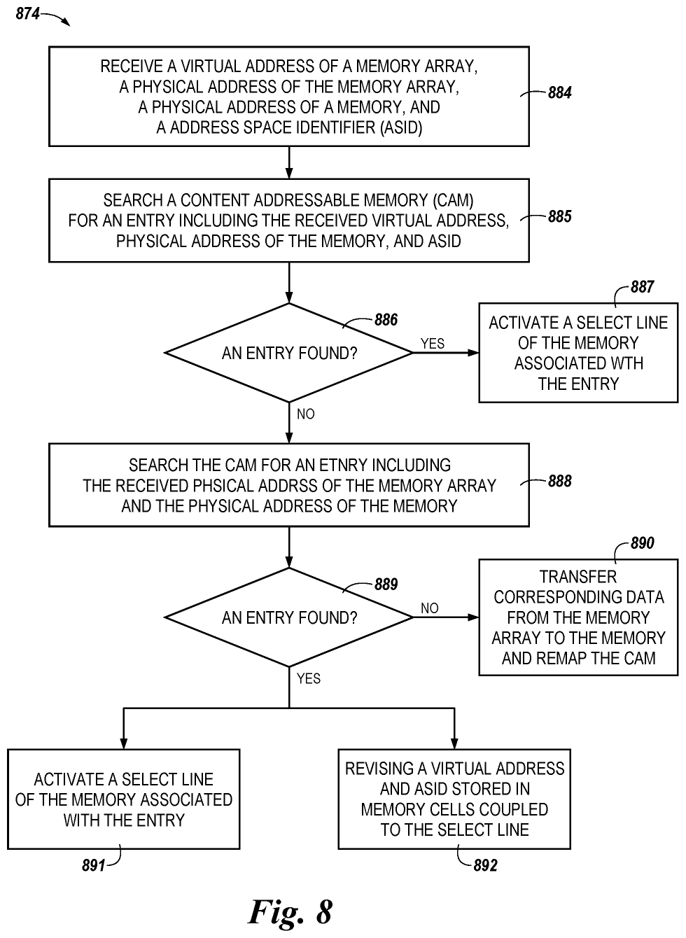

In some instances, two or more processes, tasks, threads, and/or application may reference the same physical address of the memory array. Such a physical address can be referred to as a “synonym.” Uncontrolled writes to synonyms by multiple processes could result in errors and/or malfunctions of the memory array. At least one embodiment of the present disclosure provides a solution to a synonym problem. For example, the CAM 312 can be configured to, responsive to a wired OR operation performed by the CAM 312 on a received virtual address determining that two or more of the rows 322 of the CAM 312 store the received virtual address and a same physical address of the memory 316, perform another wired OR operation on a received physical address (pAdr) of the memory array associated with the virtual address and a received physical address (cTag) of the memory 316, and physical addresses of the memory array 316 and physical addresses of the memory 316 stored in the fifth and sixth portions 348 and 350 of the CAM 312, to determine whether the synonym physical address of the memory array is owned by a different processes, tasks, threads, and/or applications. The CAM 312 can be configured to, responsive to the other wired OR operation determining that the received physical address is stored in one of the rows 322 of the CAM 312, cause an entry of the memory 316 to be appropriated. Further details of handling a synonym problem are described in connection with FIG. 8.

In at least one embodiment, the CAM 312 can be used to identify synonyms. The CAM 312 can be used to identify rows on a same page but different cache lines (e.g., sibling rows). The CAM 312 can be used to identify one or more cache lines owned by a particular process. The cache lines can be cleared when the process is terminated, for example. The CAM 312 can be used to identify and enforce read-only and/or other privileged access to data.

In a non-limiting example, an example apparatus can include a memory (e.g., memory 116 described in association with FIG. 1) including a plurality of first select lines and a CAM (e.g., CAM 112 described in association with FIG. 1) including a plurality of second select lines. Each of the plurality of second select lines can be coupled to a respective one of the plurality of first select lines. In this example, the CAM can be configured to receive, from a host (e.g., host 102 described in association with FIG. 1), signals indicative of a virtual address of a memory array (e.g., memory array 118 described in association with FIG. 1). In response to receipt of the signals, the CAM can be further configured to compare the received virtual address to each one of virtual addresses stored in respective memory cells coupled to each one of the plurality of second select lines, and determine, based at least in part on the comparison, whether memory cells coupled to one of the plurality of second select lines stores a virtual address of the virtual addresses matching the received virtual address. In response to a determination that memory cells coupled to a particular one of the plurality of second select lines stores a virtual address matching the received virtual address, the CAM can be configured to activate a corresponding select line of the plurality of first select lines coupled to the particular one of the plurality of second select lines.

In some embodiments, the CAM can be configured to compare the received virtual address simultaneously to each one of the virtual addresses stored in the respective memory cells coupled to each one of the plurality of second select lines. In some embodiments, the memory can include static random-access memory (SRAM).

In some embodiments, a portion of memory cells coupled to each one of the plurality of select lines of the CAM can be configured to store an index associated with each select line of the CAM. In some embodiments, a first portion of memory cells coupled to each one of the plurality of select lines of the CAM can be configured to store a data value indicative of data stored in the memory cells being read-only, and a second portion of memory cells coupled to each one of the plurality of select lines of the CAM can be configured to store a data value indicative of data stored in the memory cells being execute-only.

In some embodiments, a first portion of memory cells coupled to each one of the plurality of select lines of the CAM can be configured to store a data value indicative of data stored in the memory cells being locked. Further, a second portion of memory cells coupled to each one of the plurality of select lines of the CAM can be configured to store a data value indicative of data stored in the memory cells being a page table entry. Further, a third portion of memory cells coupled to each one of the plurality of select lines of the CAM can be configured to store a data value indicative of data stored in the memory cells being dirty.

In another non-limiting example, a content addressable memory (CAM) (e.g., CAM 112 described in association with FIG. 1) can include a plurality of rows of memory cells (e.g., rows 322 described in association with FIG. 1). Each of the plurality of rows can be directly coupled to a respective row of memory cells of a memory (e.g., memory 116 described in association with FIG. 1) and a first portion of each row of the CAM can be configured to store a virtual address of a memory array (e.g., memory array 118 described in association with FIG. 1). In this example, the CAM can be configured to receive signals comprising data values indicative of a virtual address of the memory array and a corresponding physical address of the memory and enable, in response to receipt of the signals, the first portion of each row of the CAM. In response to the first portion being enable, the CAM can be configured to search a data value that matches a data value corresponding to the received virtual address among data values stored in the first portion of each row.

In some embodiments, the CAM can be configured to identify a row of the plurality of rows of the CAM whose first portion storing a data value that matches the data value corresponding to the received virtual address. In this example, the CAM can be further configured to enable, to activate a corresponding row of memory cells of the memory coupled to the identified row of the CAM, the identified row of the plurality of rows of the CAM. The CAM can be further configured to disable other rows of the plurality of rows of the CAM such that the other rows of the plurality of rows of the CAM are not activated (at least while data stored in the corresponding row of the CAM are being transferred back to a host, such as host 102 described in association with FIG. 1).

In some embodiments, a second portion of each row of the CAM can be configured to store a physical address of a main memory coupled to the memory. In this example, the CAM can be configured to prevent, in response to receipt of the signals, the second portion from being enabled such that physical addresses stored in the second portion of each row of memory cells are not, in response to receipt of the signals, compared to the corresponding physical address.

In some embodiments, a third portion of each row of the CAM can be configured to store an address space identifier (ASID) and a fourth portion of each row of the CAM can be configured to store a physical address of the memory. In an example where the received signals include data values respectively corresponding to an ASID and a physical address of the memory along with the data values corresponding to the received virtual address, the CAM can be further configured to enable, along with the first portion, the third portion and the fourth portion. In this example, the CAM can be further configured to search, in response to the third portion and the fourth portion being enabled along with the first portion, data values that respectively match the data values corresponding to the ASID and the physical address of the memory of the received signals.

In some embodiments, each portion of the plurality of rows of memory cells of the CAM can be coupled to a respective register of the CAM. In this example, the CAM can be configured to control each register to enable or disable a corresponding portion. In some embodiments, the CAM can be configured to perform a wired exclusive OR (XOR) operation to determine whether the data value stored in the first portion of each row matches the data value corresponding to the received virtual address.

In another non-limiting example, a system can include a host (e.g., host 102 described in association with FIG. 1) and a memory system coupled to the host. The memory system can include a main memory and control circuitry (e.g., control circuitry 110 described in association with FIG. 1). The main memory can correspond to a memory array 118 described in association with FIG. 1. The control circuitry can include a memory (e.g., memory 116 described in association with FIG. 1) and a content addressable memory (CAM) (e.g., CAM 112 described in association with FIG. 1) including a plurality of rows of memory cells each storing a respective entry. Each of the plurality of rows of memory cells can be coupled to a respective row of memory cells of the memory. In this example, the CAM can be configured to receive, from a host, signals indicative of a virtual address of the main memory, and identify, among entries stored in the plurality of rows of memory cells of the CAM, an entry comprising a virtual address matching the received virtual address received from the host. In response to the entry being identified, the CAM can be further configured to disabling other rows of the CAM except for a row comprising the identified entry.

In some embodiments, the CAM can be configured to enable, while the other rows of the CAM are being disabled, the row comprising the identified entry, which enables a corresponding row of memory cells of the memory coupled to the row comprising the identified entry. In some embodiments, the memory can be a cache.

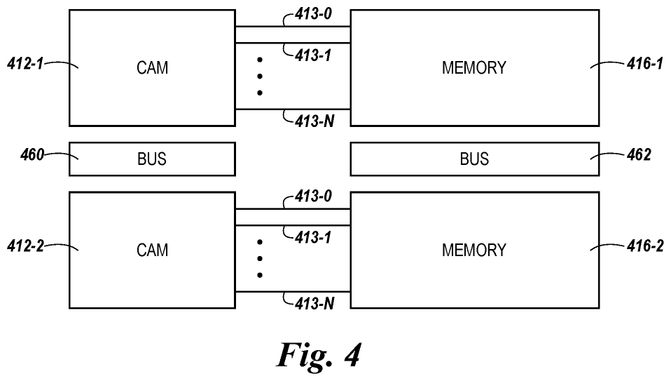

FIG. 4 is a block diagram of an apparatus for mapping a virtual address using CAMs 412-1 and 412-2 in accordance with a number of embodiments of the present disclosure. FIG. 1 illustrates the memory device 106 including a single CAM 112 coupled to a single memory 116; however, embodiments are not so limited. As illustrated by FIG. 412, a first CAM 412-1 (e.g., a first CAM tile) can be coupled to a first memory 416-1 (e.g., a first SRAM tile) and a second CAM 412-2 (e.g., a second CAM tile) can be coupled to a second memory 416-2 (e.g., a second SRAM tile). The first CAM 412-1 can be in communication with the second CAM 412-2 via a first bus 460 (e.g., an address bus). The first memory 416-1 can be in communication with the second memory 416-2 via a second bus 462. The CAM 112 can be analogous to the first CAM 412-1 in communication with the second CAM 412-2 via the first bus 460. The memory 116 can be analogous to the first memory 416-1 in communication with the second memory 416-2 via the second bus 462

Although FIG. 4 illustrates N+1 rows of the CAMs 412-1 and 412-2 being coupled to N+1 rows of the memories 416-1 and 416-2 as represented by the lines 413-0, 413-1, . . . 413-N, embodiments of the present disclosure are not so limited. The quantity of connections between respective rows of the CAM 412-1 and respective rows of the memory 416-1 can be greater or fewer than the quantity of connections between respective rows of the CAM 412-2 and respective rows of the memory 416-2. For example, N+1 rows of the CAM 412-1 can be coupled to N+1 rows of the memory 416-1 and N+2 rows of the CAM 412-2 can be coupled to N+2 rows of the memory 416-2.

Although FIG. 4 shows two CAMs 412-1 and 412-2 coupled to a respective memory 416-1 and 416-2; embodiments are not so limited. For example, a third CAM (not shown) can be coupled to a third memory (not shown). The second CAM 412-2 can be in communication with the third CAM via a third bus (not shown) and the second memory 416-2 can be in communication with the third memory via a fourth bus (not shown).

FIG. 5 illustrates a memory cell 536 of a memory in accordance with a number of embodiments of the present disclosure. The memory cell 536 is a SRAM cell. The memory cell 536 can be analogous to the memory cells 236 of the memory 216 described in association with FIG. 2. However, embodiments of the present disclosure are not limited to the memory 216 being SRAM or memory cells of the memory 216 having the structure illustrated by FIG. 5.

The memory cell 536 can include a latch 552. The latch 552 can include a pair of cross-coupled n-type transistors and a pair of cross-coupled p-type transistors. The memory cell 536 can include a first n-type transistor 561 having a gate coupled to a first signal line (WRITE ROW) 556 of a CAM (e.g., the CAM 212). A first source/drain region of the first n-type transistor 561 can be coupled to a second signal line (WRITE DIGIT TRUE) 553 of the CAM and a second source/drain region of the first n-type transistor 561 can be coupled to the latch 552. The memory cell 536 can include a second n-type transistor 563 having a gate coupled to the first signal line (WRITE ROW) 556 of the CAM. A first source/drain region of the second n-type transistor 563 can be coupled to the latch 552 and a second source/drain region of the second n-type transistor 563 can be coupled to a third signal line (WRITE DIGIT COMPLEMENT) 554 of the CAM.

The memory cell 536 can include a third n-type transistor 575 having a gate coupled to a fourth signal line (READ ROW) 557 of the CAM. A first source/drain region of the third n-type transistor 575 can be coupled to a fifth signal line (READ DIGIT COMPLEMENT) 551 of the CAM and a second source/drain region of the third n-type transistor 575 can be coupled to a first source/drain region of a fourth n-type transistor 577 of the memory cell 536. A gate of the fourth n-type transistor 577 can be coupled to the latch 552 and the second source/drain region of the first n-type transistor 561. A second source/drain region of the fourth n-type transistor 577 can be coupled to a supply voltage (Vss).

The memory cell 536 can include a fifth n-type transistor 571 having a gate coupled to the fifth signal line (READ ROW) 557. A first source/drain region of the fifth n-type transistor 571 can be coupled to a sixth signal line (READ DIGIT TRUE) 555 of the CAM and a second source/drain region of the fifth n-type transistor 571 can be coupled to a first source/drain region of a sixth n-type transistor 573 of the memory cell 536. A gate of the sixth n-type transistor 573 can be coupled to the latch 552 and the first source/drain region of the second n-type transistor 563. A second source/drain region of the sixth n-type transistor 573 can be coupled to the supply voltage (Vss).

FIG. 6 illustrates a CAM cell 626 of a CAM in accordance with a number of embodiments of the present disclosure. The CAM cell 626 can be analogous to the CAM cells 226 of the CAM 212 described in association with FIG. 2. However, embodiments of the present disclosure are not limited to memory cells of the CAM 212 having the structure as illustrated by FIG. 6.

The CAM cell 626 can include a latch 664. The latch 664 can include a pair of cross-coupled n-type transistors and a pair of cross-coupled p-type transistors. The CAM cell 626 can include a first n-type transistor 665 having a gate coupled to a first signal line (WRITE ROW) 682 of a memory (e.g., the memory 216). A first source/drain region of the first n-type transistor 665 can be coupled to a second signal line (WRITE DIGIT TRUE) 679 of the memory and a second source/drain region of the first n-type transistor 665 can be coupled to the latch 664. The CAM cell 626 can include a gate of a second n-type transistor 667 coupled to the first signal line (WRITE ROW) 682 of the memory. A first source/drain region of the second n-type transistor 667 can be coupled to the latch 664 and a second source/drain region of the second n-type transistor 667 can be coupled to a third signal line (WRITE DIGIT COMPLEMENT) 680 of the memory.

The CAM cell 626 can include a third n-type transistor 670 having a gate coupled to a fourth signal line (MATCH DATA TRUE) 678 of the memory. A first source/drain region of the third n-type transistor 670 can be coupled to a fifth signal line (WIRED OR MATCH) 683 of the memory and a second source/drain region of the third n-type transistor 670 can be coupled to a first source/drain region of a fourth n-type transistor 672 of the CAM cell 626. A gate of the fourth n-type transistor 672 can be coupled to the latch 552 and the second source/drain region of the first n-type transistor 665. A second source/drain region of the fourth n-type transistor 672 can be coupled to a supply voltage (Vss).

The CAM cell 626 can include a fifth n-type transistor 668 having a gate coupled to a sixth signal line (MATCH DATA COMPLEMENT) 681. A first source/drain region of the fifth n-type transistor 668 can be coupled to the fifth signal line (WIRED OR MATCH) 683 and a second source/drain region of the fifth n-type transistor 668 can be coupled to a first source/drain region of a sixth n-type transistor 669 of the CAM cell 626. A gate of the sixth n-type transistor 689 can be coupled to the latch 664 and the first source/drain region of the second n-type transistor 667. A second source/drain region of the sixth n-type transistor 669 can be coupled to the supply voltage (Vss).

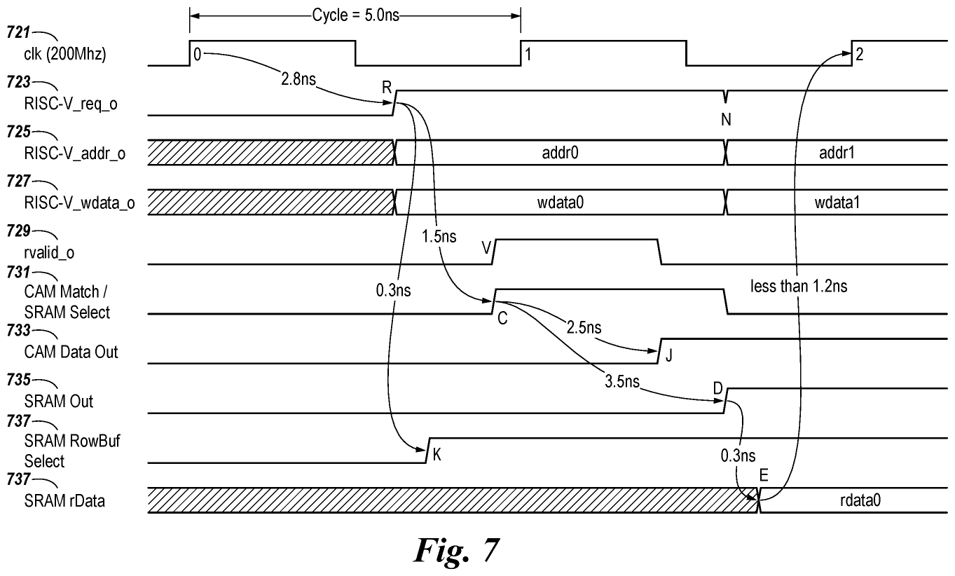

FIG. 7 is a timing diagram of a memory device for mapping a virtual address using a CAM in accordance with a number of embodiments of the present disclosure. The memory device described in association with FIG. 7 can be the memory device 106 described in association with FIG. 1. Time intervals shown in FIG. 7 are exemplary, non-limiting, and intended to illustrate a benefit of at least one embodiment of the present disclosure. Signal 721 (clk) is a clock of a processing resource of a host (e.g., the processing resource 104 of the host 102). As illustrated by signal 721, the processing resource of the host is operating at two hundred megahertz (mHz) such that a clock cycle is approximately five nanoseconds (ns) long.

From the rising edge of clock cycle 0 of the signal 721 to point R represents an exemplary time for a processing resource (e.g., a RISC-V processor) of the memory device (e.g., the processing resource 108 of the memory device 106) to assert a read and/or write request. The time from the rising edge of clock cycle 0 to point R can be approximately 2.8 ns, for example.

From point R on signal 723 (RISC-V_req_o) to point C on signal 731 (CAM Match/SRAM Select) represents an exemplary time for CAM (e.g., the CAM 112) to perform a lookup operation (e.g., perform a wired OR operation) for a received address associated with a read and/or write request. The time from the point R to point C can be approximately 1.5 ns, for example.

From point C on the signal 731 (CAM Match/SRAM Select) to point D on signal 735 (SRAM Out) represents an exemplary time for a memory (e.g., the memory 116) to access a row activated by the CAM as a result of the lookup operation and select a word from an output buffer. The time from the point C to point D can be approximately 3.5 ns, for example.

From point C on the signal 731 (CAM Match/SRAM Select) to point J on signal 733 (CAM Data Out) represents an exemplary time for the CAM to activate a row of the memory as a result of the lookup operation. The time from the point C to point J can be approximately 2.5 ns, for example. Point J refers to when data values identified by the lookup operation performed by the CAM is available to a state machine (e.g., the state machine 114).

From point E on signal 737 (SRAM rData) to the rising edge of clock cycle 2 of the signal 721 represents an exemplary time between output of the selected word from the memory to the rising edge of next clock cycle (clock cycle 2). The time from the point C to point J can be less than or equal to approximately 1.2 ns, for example.

Events triggered at point R can be timed by the signal 723, which can be internal to the memory device and independent of the signal 721. Point V on signal 729 (rvalid_o) can rise before the rising edge of clock cycle 1 of the signal 721. The signal 729 can be contemporaneous with the signal 731 (CAM Match/SRAM Select) and activated before the rising edge of the next clock cycle (the clock cycle 1). The signal 729 (rvalid_o) can indicate to the processing resource of the host that valid data will be available in clock cycle 1 of the signal 721 (i.e., before the rising edge of clock cycle 2 of the signal 721). This can enable the processing resource of the host to initiate another operation at point N on signal 723. Point N is at approximately the same relative location within clock cycle 0 of the signal 721 as point Ron the signal 723 within clock cycle 1 of the signal 721. The memory device may not alter the data value returned from the request at point R until clock cycle 2 of the signal 721.

FIG. 8 is a flow diagram of a method 874 for performing a lookup operation on data values stored in a CAM in accordance with a number of embodiments of the present disclosure. At block 884, a CAM can receive (e.g., signals indicative of) a virtual address of a memory array, a physical address of the memory array, a physical address of a memory, and an ASID from a host (is this right?) and to be searched within the CAM. The CAM, memory array, memory, and host can correspond to CAM 112, memory array 118, memory 116, and host 102, respectively, as illustrated in FIG. 1.

At block 885, the CAM can be configured to search an entry including the received virtual address, physical address of the memory, and ASID. For example, the CAM can enable respective columns of the CAM corresponding to the virtual address, the physical address of the memory, and the ASID (e.g., columns 346, 348, and 352 as illustrated in FIG. 3), which enables the CAM to perform the wired OR operation that compares the received virtual address, physical address of the memory, and ASID to those corresponding data values stored in the enabled columns.

At block 886, a determination is made whether an entry (e.g., single entry) having the received virtual address, physical address of the memory, and ASID is found. If it is determined that the entry having the received virtual address, physical address of the memory, and ASID is found, the method 874 proceeds to block 887, in which a select line of the memory coupled to a select line associated with the entry (e.g., the select line coupled to memory cells storing data values associated with the received virtual address, physical address of the memory, and ASID) is activated, and data stored in the memory cells coupled to the select line of the memory is provided back to the host.

If it is determined that the entry is not found, the method 874 proceeds to block 888, in which another lookup operation is performed again on different data values stored within the CAM. For example, at block 888, the CAM can be configured to enable respective columns of the CAM corresponding to the received physical address of the memory and the physical address of the memory array (e.g., columns 348 and 350 as illustrated in FIG. 3) such that the CAM can be configured to search an entry including the received physical address of the memory and the physical address of the memory array.

At block 889, a determination is made whether an entry (e.g., single entry) having the received physical address of the memory and the physical address of the memory array is found. If it is determined that the entry having the received physical address of the memory and the physical address of the memory array is not found, the method 874 proceeds to block 890. At block 890, data corresponding to the received physical address of the memory array can be transferred to the memory (e.g., as the memory didn't include data corresponding to the received physical address of the memory array) and the CAM can be remapped to include one entry corresponding to the data transferred from the memory array to the memory. If all entries of the CAM is currently in use (e.g., mapped to a corresponding physical address of the memory and/or the memory array), one of the entries of the CAM can be reprogrammed to map the reprogrammed entry to the received physical address of the memory array.

If it is determined that the entry having the received physical address of the memory and the physical address of the memory array is found, the method 874 proceeds to block 891 and/or block 892. At block 891, a select line of the memory coupled to a select line associated with the entry (e.g., the select line coupled to memory cells storing data values associated with the received physical address of the memory and physical address of the memory array) is activated, and data stored in the memory cells of the select line of the memory is provided back to the host.

At block 892 (e.g., simultaneously with block 891), the CAM can be configured to revise a virtual address and an ASID of the entry. As described herein, as an example, uncontrolled writes (e.g., from multiple users and/or multiples writes from a user) can undesirably alter a virtual address and an ASID stored in an entry, which can lead to a lookup operation performed on a virtual address of the memory array not finding a desired entry even when the entry exists within the CAM. Therefore, upon confirming that a physical address of the memory and a physical address of a memory array of the entry (e.g., whose virtual address and ASID may have been undesirably altered) matches to the received physical address of the memory and the physical address of the memory array, the CAM can be configured to replace the undesirably altered virtual address and the ASID respectively with the received virtual address and the ASID (e.g., that are received along with the received physical address of the memory and the received physical address of the memory array). Accordingly, embodiments of the present disclosure can provide a solution to the synonym problem by performing multiple lookup operations on different types of data values stored in the CAM.

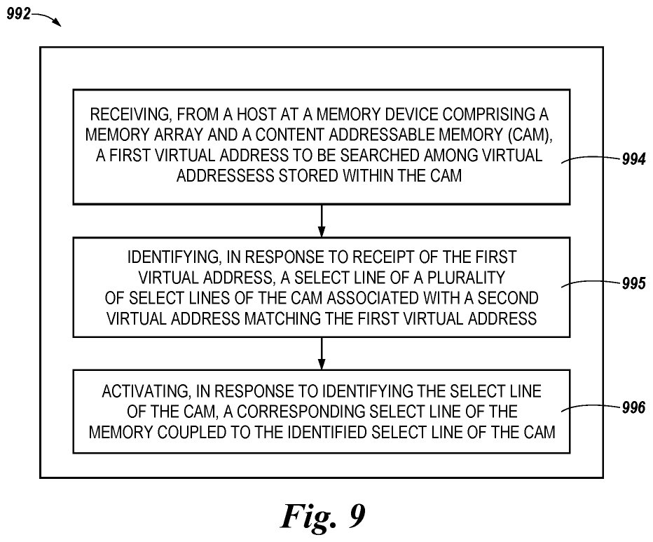

FIG. 9 is a flow diagram of a method 992 for mapping a virtual address using a CAM in accordance with a number of embodiments of the present disclosure.

At block 994, the method 992 can include receiving, from a host at a memory device comprising a memory array and a content addressable memory (CAM), a first virtual address to be searched among virtual addresses stored within the CAM At block 995, the method 992 can include identifying, in response to receipt of the first virtual address, a select line of a plurality of select lines of the CAM associated with a second virtual address matching the first virtual address. In some embodiments, identifying the select line of the plurality of select lines of the CAM associated with the second virtual address matching the first virtual address comprises performing a wired exclusive OR (XOR) operation between virtual addresses stored in the CAM and the first virtual address.

At block 996, the method 992 can include activating, in response to identifying the select line of the CAM, a corresponding select line of the memory coupled to the identified select line of the CAM. Activating the corresponding select line of the memory coupled to the identified select line of the CAM can include, for example, activating the corresponding select line of the memory by activating the identified select line of the CAM.

In some embodiments, the method 992 can also include transferring, subsequent to activating the corresponding select line of the memory, data stored in the corresponding select line of the memory back to the host. In some embodiments, the method 992 can also include receiving, along with the first virtual address, a corresponding address space identifier (ASID) and a corresponding physical address of the memory and determining whether the corresponding ASID and the corresponding physical address of the memory respectively match an ASID and a physical address of the memory stored in the select line of the CAM. In this example, the method 992 can include activating the select line of the CAM when the virtual address, the ASID, and the physical address of the memory stored in the select line of the CAM respectively match the received corresponding virtual address, corresponding ASID, and the corresponding physical address of the memory.

Although specific embodiments have been illustrated and described herein, those of ordinary skill in the art will appreciate that an arrangement calculated to achieve the same results can be substituted for the specific embodiments shown. This disclosure is intended to cover adaptations or variations of one or more embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the one or more embodiments of the present disclosure includes other applications in which the above structures and methods are used. Therefore, the scope of one or more embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method, comprising:
receiving, from a host at a memory device comprising a memory array and a content addressable memory (CAM), a first virtual address to be searched among virtual addresses stored within the CAM;
identifying, in response to receipt of the first virtual address, a select line of a plurality of select lines of the CAM associated with a second virtual address matching the first virtual address; and
activating, in response to identifying the select line of the CAM, a corresponding select line of the memory coupled to the identified select line of the CAM.

2. The method of claim 1, wherein activating the corresponding select line of the memory coupled to the identified select line of the CAM comprises activating the corresponding select line of the memory by activating the identified select line of the CAM.

3. The method of claim 1, further comprising transferring, subsequent to activating the corresponding select line of the memory, data stored in the corresponding select line of the memory back to the host.

4. The method of claim 1, wherein identifying the select line of the plurality of select lines of the CAM associated with the second virtual address matching the first virtual address comprises performing a wired exclusive OR (XOR) operation between virtual addresses stored in the CAM and the first virtual address.

5. The method of claim 1, further comprising:
receiving, along with the first virtual address, a corresponding address space identifier (ASID) and a corresponding physical address of the memory; and
determining whether the corresponding ASID and the corresponding physical address of the memory respectively match an ASID and a physical address of the memory stored in the select line of the CAM.

6. The method of claim 5, further comprising activating the select line of the CAM when the virtual address, the ASID, and the physical address of the memory stored in the select line of the CAM respectively match the received corresponding virtual address, corresponding ASID, and the corresponding physical address of the memory.

7. An apparatus, comprising:
a memory including a plurality of first select lines; and
a content addressable memory (CAM) including a plurality of second select lines, wherein each of the plurality of second select line is coupled to a respective one of the plurality of first select lines;
wherein the CAM is configured to:
receive, from a host, signals indicative of a virtual address of a memory array; and
in response to receipt of the signals:
compare the received virtual address to each one of virtual addresses stored in respective memory cells coupled to each one of the plurality of second select lines;
determine, based at least in part on the comparison, whether memory cells coupled to one of the plurality of second select lines stores a virtual address of the virtual addresses matching the received virtual address; and
activate, in response to a determination that memory cells coupled to a particular one of the plurality of second select lines stores a virtual address matching the received virtual address, a corresponding select line of the plurality of first select lines coupled to the particular one of the plurality of second select lines.

8. The apparatus of claim 7, wherein the CAM is configured to compare the received virtual address simultaneously to each one of the virtual addresses stored in the respective memory cells coupled to each one of the plurality of second select lines.

9. The apparatus of claim 7, wherein the memory comprises static random-access memory (SRAM).

10. The apparatus of claim 7, wherein a portion of memory cells coupled to each one of the plurality of select lines of the CAM is configured to store an index associated with each select line of the CAM.

11. The apparatus of claim 7, wherein:
a first portion of memory cells coupled to each one of the plurality of select lines of the CAM is configured to store a data value indicative of data stored in the memory cells being read-only; and
a second portion of memory cells coupled to each one of the plurality of select lines of the CAM is configured to store a data value indicative of data stored in the memory cells being execute-only.

12. The apparatus of claim 7, wherein:
a first portion of memory cells coupled to each one of the plurality of select lines of the CAM is configured to store a data value indicative of data stored in the memory cells being locked;
a second portion of memory cells coupled to each one of the plurality of select lines of the CAM is configured to store a data value indicative of data stored in the memory cells being a page table entry; and
a third portion of memory cells coupled to each one of the plurality of select lines of the CAM is configured to store a data value indicative of data stored in the memory cells being dirty.

13. A content addressable memory (CAM), comprising:
a plurality of rows of memory cells, each directly coupled to a respective row of memory cells of a memory, wherein a first portion of each row of the CAM is configured to store a data value indicative of a virtual address of a memory array; and
the CAM is configured to:
receive signals comprising data values indicative of a virtual address of the memory array and a corresponding physical address of the memory;
enable, in response to receipt of the signals, the first portion of each row of the CAM; and
search, in response to the first portion being enabled, a data value that matches a data value corresponding to the received virtual address among data values stored in the first portion of each row.

14. The CAM of claim 13, wherein the CAM is configured to:
identify a row of the plurality of rows of the CAM whose first portion storing a data value that matches the data value corresponding to the received virtual address; and
enable, to activate a corresponding row of memory cells of the memory coupled to the identified row of the CAM, the identified row of the plurality of rows of the CAM.

15. The CAM of claim 14, wherein the CAM is configured to disable other rows of the plurality of rows of the CAM such that the other rows of the plurality of rows of the CAM are not activated.

16. The CAM of claim 13, wherein a second portion of each row of the CAM is configured to store data values indicative of respective physical addresses of the memory array coupled to the memory, and wherein:
the CAM is configured to prevent, in response to receipt of the signals, the second portion from being enabled such that the data values indicative of the respective physical addresses stored in the second portion are not, in response to receipt of the signals, compared to a data value indicative of the corresponding physical address.

17. The CAM of claim 13, wherein:
a third portion of each row of the CAM is configured to store a data value indicative of an address space identifier (ASID); and
a fourth portion of each row of the CAM is configured to store a data value indicative of a physical address of the memory.

18. The CAM of claim 17, wherein:
the received signals comprises data values respectively corresponding to an ASID and a physical address of the memory along with the data values corresponding to the received virtual address; and
the CAM is configured to:
enable, along with the first portion, the third portion and the fourth portion; and
search, in response to the third portion and the fourth portion being enabled along with the first portion, data values that respectively match the data values corresponding to the ASID and the physical address of the memory of the received signals.

19. The CAM of claim 13, wherein each portion of the plurality of rows of memory cells of the CAM is coupled to a respective register of the CAM, wherein the CAM is configured to control each register to enable or disable a corresponding portion.

20. The CAM of claim 13, wherein the CAM is configured to perform a wired exclusive OR (XOR) operation to determine whether the data value stored in the first portion of each row matches the data value corresponding to the received virtual address.

21. A system, comprising:
a host; and
a memory system coupled to the host and comprising:
a main memory; and
control circuitry coupled to the main memory and comprising:
a memory; and
a content addressable memory (CAM) comprising a plurality of rows of memory cells each storing a respective entry, wherein each of the plurality of rows of memory cells is coupled to a respective row of memory cells of the memory;
the CAM configured to:
receive, from the host, signals indicative of a virtual address of the main memory;
identify, among entries stored in the plurality of rows of memory cells of the CAM, an entry comprising a virtual address matching the received virtual address received from the host; and
disabling, in response to the entry being identified, other rows of the CAM except for a row comprising the identified entry.

22. The system of claim 21, wherein the CAM is configured to enable, while the other rows of the CAM are being disabled, the row comprising the identified entry, which enables a corresponding row of memory cells of the memory coupled to the row comprising the identified entry.

23. The system of claim 22, wherein the memory is a cache.
